(19) United States
(12) Patent Application Publication
(10) Pub. No.: US 2008/0081487 A1
(43) Pub. Date: Apr. 3, 2008

(54) Method for fabricating semiconductor element

(75) Inventors: Tetsumi Tominaga, Miyazaki (JP); Teruhisa Fukuda, Miyazaki (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 11/529,289

(22) Filed: Sep. 29, 2006

(51) Int. Cl. H01L 21/00

(52) U.S. Cl. 438/795

(57) ABSTRACT

According to this invention, a method for fabricating a semiconductor element comprises the steps of providing a semiconductor wafer; forming an oxide layer on the semiconductor wafer; loading the semiconductor wafer in a furnace; carrying out a high-temperature thermal treatment to the semiconductor wafer at least once, wherein the high-temperature thermal treatment comprises a final high-temperature treatment, which is carried out lastly as the high-temperature thermal treatment; maintaining the semiconductor wafer left in the furnace in an oxidizing atmosphere for a predetermined period of time after the final high-temperature treatment; and unloading the semiconductor wafer from the furnace after the maintaining process in oxidizing atmosphere.

### TECHNICAL FIELD OF THE INVENTION

This invention relates to a semiconductor integrated circuit, and more particularly to, a method for fabricating a semiconductor element, such as a resistive element.

### BACKGROUND OF THE INVENTION

In general, a resistive element to be used in a semiconductor integrated circuit is fabricated by a process including the steps of ion implantation of impurity into a semiconductor wafer; and a thermal treatment, for example, annealing, to activate it. For instance, boron is implanted into a semiconductor Si wafer through the screen oxide layer. Next, annealing process is carried out to the wafer to form a P-type diffused resistor.

However, according to a conventional method, a variety of electric charge is trapped between a screen oxide layer and a semiconductor wafer, and therefore, a surface potential of the semiconductor wafer may be changed. As a result, characteristics of a diffused resistor formed on the semiconductor wafer are fluctuated. Such a fluctuation is caused by electric charge trapped between a screen oxide layer and a semiconductor wafer. This kind of problem is remarkable for a high-resistivity element.

Since electric charge is trapped on a side of an oxide layer, such electric charge can be removed by removing the oxide layer with hydrofluoric acid. However, another electric charge is generated in following thermal treatments. Conventional technology relating to a density of electric charge is described in a reference, J. Electrochem. Soc: SOLID STATE SCIENCE, March 1967, pp 266-273, and J. Electrochem. Soc: SOLID STATE SCIENCE, September 1971, pp 1463-1468.

### OBJECTS OF THE INVENTION

Accordingly, an object of this invention is to provide an improved method for fabricating a semiconductor element, having a stable density of fixed electric charge on a semiconductor wafer.

Still another object of this invention is to provide an improved method for fabricating a semiconductor element, which does not lower a throughput of the semiconductor element.

Additional objects, advantages and novel features of this invention will be set forth in part in the description that follows, and in part will become apparent to those skilled in the art upon examination of the following or may be learned by practice of the invention. The objects and advantages of the invention may be realized and attained by means of the instrumentalities and combinations particularly pointed out in the appended claims.

### SUMMARY OF THE INVENTION

The inventor of this invention found out that a density of electric charge, which is trapped at an interface between a semiconductor wafer and an oxide layer, may be fluctuated due to locations in a furnace. Also, a density of electric charge, which is trapped at an interface between a semiconductor wafer and an oxide layer, may be fluctuated due to how wafers are unloaded from a furnace after a high-temperature thermal treatment that is carried out lastly.

According to a first aspect of this invention, a method for fabricating a semiconductor element comprises the steps of: providing a semiconductor wafer; forming an oxide layer on the semiconductor wafer; loading the semiconductor wafer in a furnace; carrying out a high-temperature thermal treatment to the semiconductor wafer at least once, wherein the high-temperature thermal treatment comprises a final high-temperature treatment, which is carried out lastly as the high-temperature thermal treatment; maintaining the semiconductor wafer left in the furnace in an oxidizing atmosphere after the final high-temperature treatment; and unloading the semiconductor wafer from the furnace after the maintaining process in oxidizing atmosphere.

According to a second aspect of this invention, a method for fabricating a resistive element on a semiconductor wafer comprise the steps of: providing a semiconductor wafer; forming a screen oxide layer on the semiconductor wafer; forming a diffusion layer on the semiconductor wafer by ion implantation and a first annealing process; loading the semiconductor wafer into a furnace; carrying out a final high-temperature treatment, which is carried out lastly as a high-temperature thermal treatment in the furnace; maintaining the semiconductor wafer left in the furnace in an oxidizing atmosphere after the final high-temperature treatment; and unloading the semiconductor wafer from the furnace after the maintaining process in oxidizing atmosphere.

### BRIEF DESCRIPTION OF THE DRAWINGS

FIG. 1 is a schematic diagram illustrating a furnace which is applicable to this invention.

FIG. 2 is a graph showing the relation between a timing of unloading of a semiconductor wafer from a furnace and a temperature thereof.

FIG. 3 is a graph showing the relation between a temperature of a wafer in an unloading process and an N-type diffused resistance.

FIG. 4 is a graph showing the relation between a temperature of a wafer in an unloading process and a P-type diffused resistance.

FIG. 5 is a flow chart showing a part of fabrication steps for a semiconductor element according to this invention.

FIG. 6 is a flow chart showing a part of fabrication steps for a semiconductor element according to this invention.

FIG. 7 is a timing chart showing an operation of a fabrication process according to an embodiment of this invention.

### DETAILED DISCLOSURE OF THE INVENTION

In the following detailed description of the preferred embodiments, reference is made to the accompanying drawings which form a part hereof, and in which is shown by way of illustration specific preferred embodiments in which the inventions may be practiced. These preferred embodiments are described in sufficient detail to enable those skilled in the art to practice the invention, and it is to be understood that other preferred embodiments may be utilized and that logical, mechanical and electrical changes may be made without departing from the spirit and scope of this invention. The following detailed description is, therefore, not to be taken in a limiting sense, and scope of this invention is defined only by the appended claims.

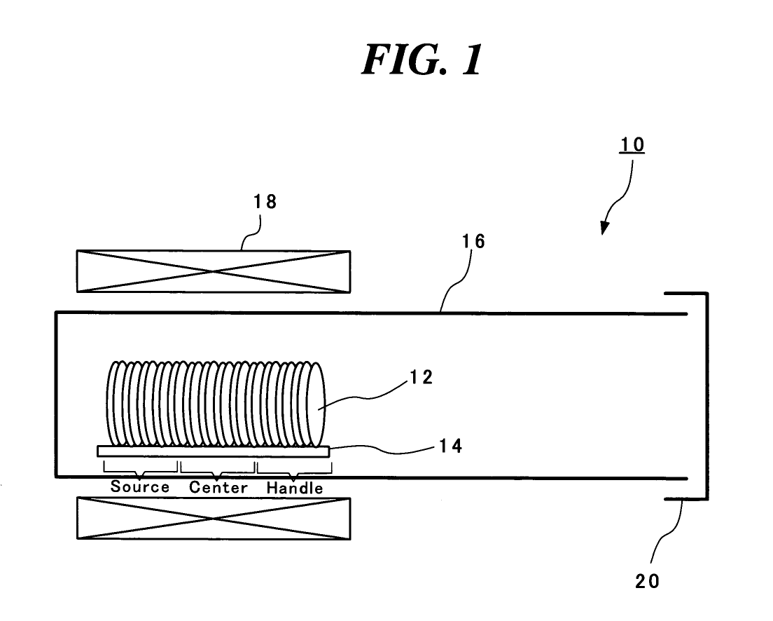

First of all, referring to FIG. 1, a furnace 10 includes a quartz tube 16, in which semiconductor wafers 12 set on a wafer boat 14 are loaded for thermal treatment. The furnace 10 also includes a heater 18 to heat the semiconductor wafers 12 loaded in the quartz tube 16, and a quartz cap 20 to seal a load/unload opening of the quartz tube 16. For easy understanding, in the quartz tube 16, an area where the deepest part of the semiconductor wafers are located is called “source”; an area where the front most part of the semiconductor wafers are located is called “handle”; and an area located between the “source” and “handle” is called “center”, as shown in FIG. 1.

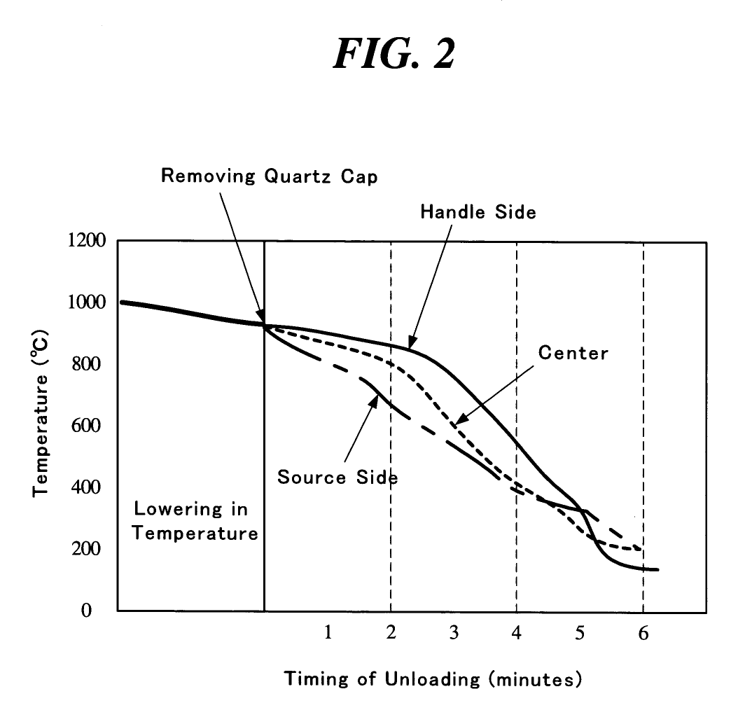

FIG. 2 is a graph showing the relation between a timing of unloading of a semiconductor wafer from the furnace 10 and a temperature thereof. In FIG. 2, “Timing of Unloading” represents a period of time measured since the quartz cap 20 is removed until the semiconductor wafers 12 are unloaded from the quartz tube 16. According to FIG. 2, the quartz cap 16 is removed when the semiconductor wafers 12 are lowered in temperature from 1000 degrees to 900 degrees.

During a period of time for lowering temperature, the semiconductor wafers 12 have almost the same temperature throughout any locations of “Source Side”, “Center” and “Handle Side”. When the quartz cap 20 is removed from the quartz tube 16, atmospheric air is introduced into the quartz tube 16, so that temperature difference is made throughout the locations “Source Side”, “Center” and “Handle Side” of the semiconductor wafers 12. Since the semiconductor wafers 12 at handle side are located relatively closer to the quartz cap 20, which can be said an opening of the quartz tube 16, the semiconductor wafers 12 at handle side are cooled down quicker than those located at the source side and the center.

For instance, a screen oxide layer having a thickness of 1000 Å is formed on a semiconductor Si wafer by a thermal oxidation process in a wet-O₂ atmosphere at 1100° C. The screen oxide layer suppresses channeling phenomenon in an ion implantation. Next, boron (acceptor) is ion-implanted into the semiconductor Si wafer under condition of 150 KeV, 1.2E13 ions/cm². Subsequently, the semiconductor wafer is annealed under condition of annealing temperature: 1100° C., process time: 20 min, and atmosphere: N₂ to form a P-type diffusion layer having a resistance value of 3.5 kohm/sq. Electric charge is trapped at an interface between the semiconductor Si wafer and the screen oxide layer.

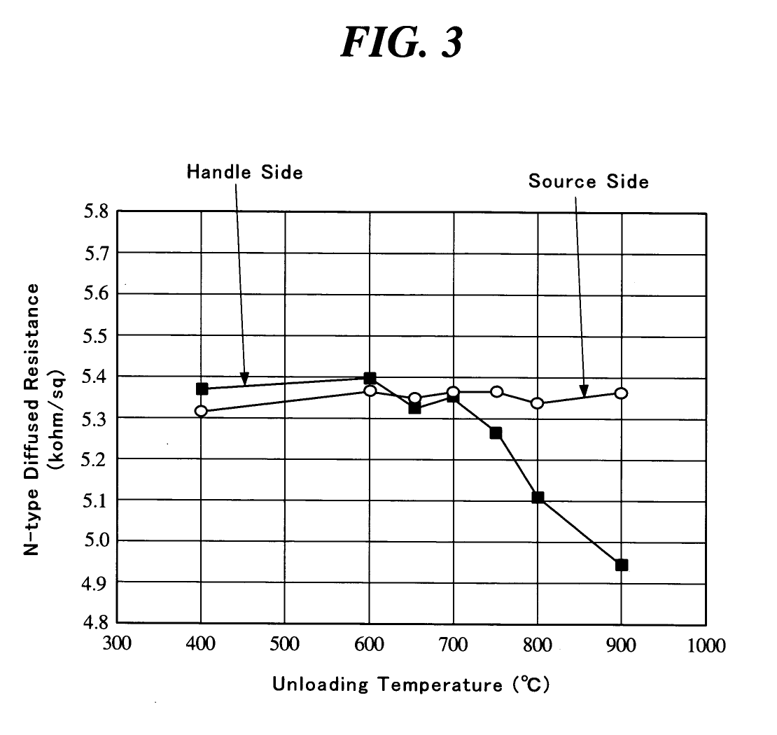

FIG. 3 is a graph showing the relation between a temperature of a wafer when unloaded and an N-type diffused resistance, formed on the semiconductor wafer. Fixed electric charge trapped at an interface between the semiconductor Si wafer and the screen oxide layer operates as a positive electric charge, so that an N-type diffused resistance formed on the semiconductor wafer becomes lower when an unloading temperature is higher than 700° C. or 600° C., as shown in FIG. 3. This kind of result is remarkable to semiconductor wafers located at the handle side in the furnace 10.

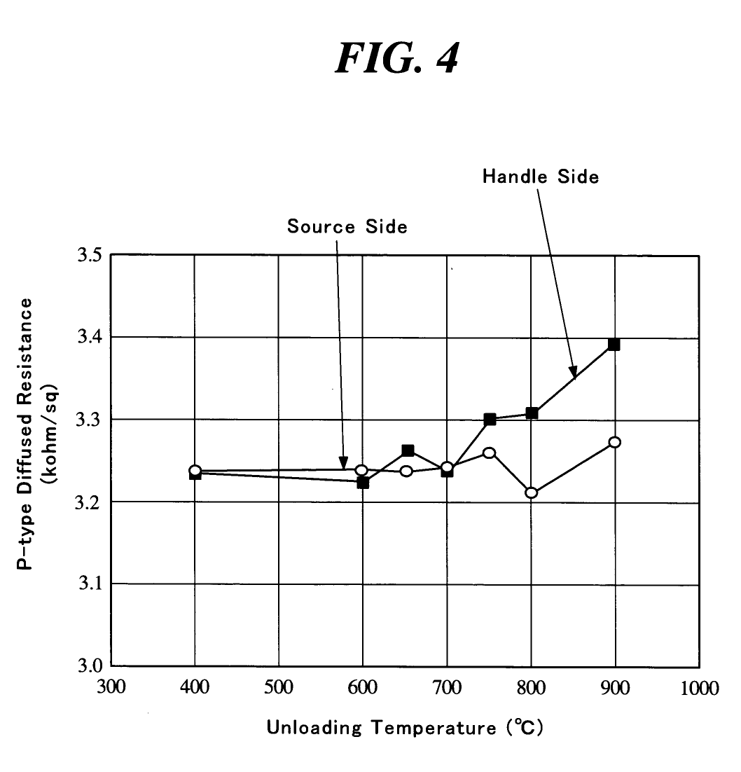

FIG. 4 is a graph showing the relation between a temperature of a wafer when unloaded and a P-type diffused resistance, formed on the semiconductor wafer. Fixed electric charge trapped at an interface between the semiconductor Si wafer and the screen oxide layer operates as a positive electric charge, so that a P-type diffused resistance formed on the semiconductor wafer becomes higher when an unloading temperature is higher than 700° C. or 600° C., as shown in FIG. 4. This kind of result is remarkable to semiconductor wafers located at the handle side in the furnace 10.

According to this invention, a high-temperature thermal treatment is carried out to the semiconductor wafers 12 at least once. The high-temperature thermal treatment includes a final high-temperature treatment, which is carried out lastly among the high-temperature thermal treatment(s).

Following the final high-temperature treatment, the temperature of the semiconductor wafers 12 is lowered to a predetermined lower temperature in an oxidizing atmosphere. When the final high-temperature treatment is finished, an oxidizing gas (oxygen) is introduced in the furnace 10 while an inert gas used for the final high-temperature treatment is exhausted. After the temperature lowering process, the semiconductor wafers 12 are unloaded from the furnace. In other words, the semiconductor wafers 12 are left in the furnace 10 in an oxidizing atmosphere for a predetermined period of time just after the final high-temperature treatment. And then, the semiconductor wafers 12 are unloaded from the furnace 10. According to another embodiment, the temperature of the semiconductor wafers 12 is not lowered intentionally but left in the oxidizing atmosphere in the furnace 10.

The high-temperature thermal treatment may be carried out plural times at 700° C. or over, preferably over 1000° C. The predetermined lower temperature may be 700° C. The final high-temperature treatment may be carried out intentionally to reduce an electric charge trapped between the oxide layer and the semiconductor wafer. The final high-temperature treatment may be carried out in an atmosphere of an inert gas. The semiconductor element may include a resistive element.

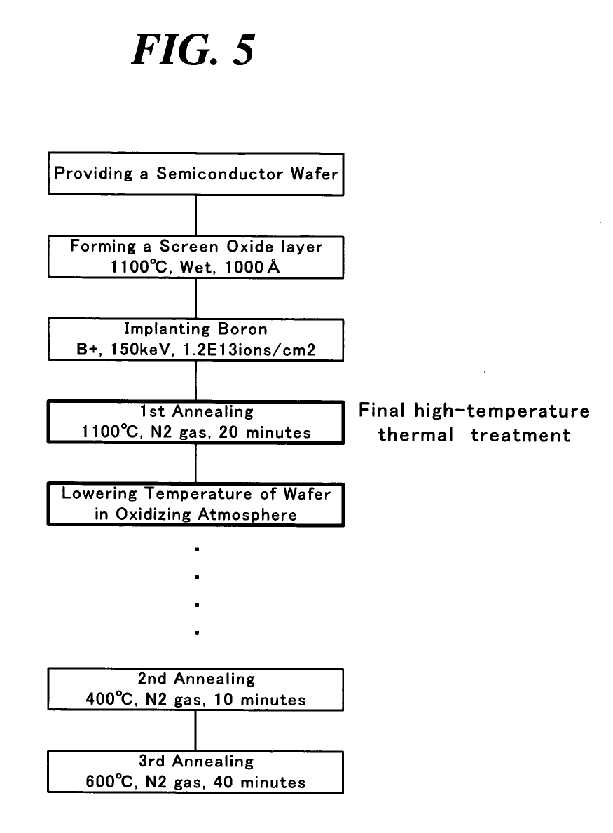

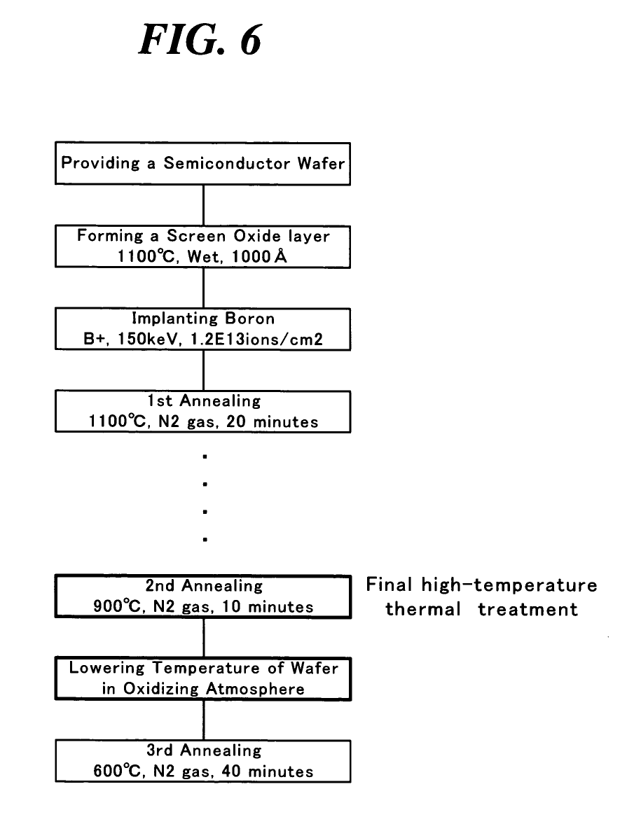

Now, “the final high-temperature treatment” is described in conjunction with FIGS. 5 and 6. “The final high-temperature treatment” means the high-temperature thermal treatment that is performed lastly among all high-temperature thermal treatment(s) at over 700° C. in the process of fabricating a semiconductor element. In the case of FIG. 5, a first annealing step corresponds to the final high-temperature thermal treatment. In the case of FIG. 6, a second annealing step corresponds to the final high-temperature thermal treatment.

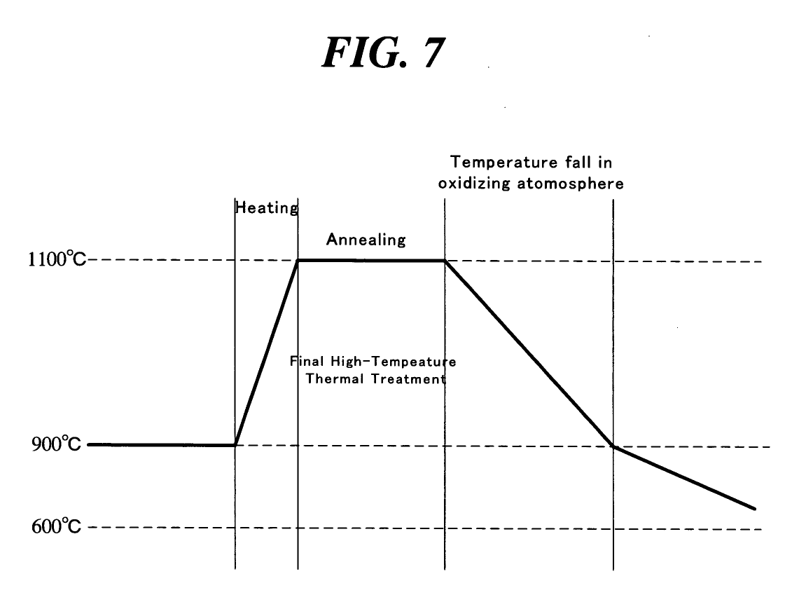

FIG. 7 is a timing chart showing an operation of the final high-temperature thermal treatment according to this invention. Now referring again to FIG. 1, according to an embodiment, firstly the semiconductor wafers 12 are set on the wafer boat 14 in advance. The inside of the quartz tube 16 are heated to 900° C. by controlling the heater 18. Next, the quartz cap 20 is opened and the wafer boat 14 with the semiconductor wafers 12 is inserted in the quartz tube 16. At this time, the wafer boat 14 is inserted to the very end of the quartz tube 16, as shown in FIG. 1. After the loading of the semiconductor wafers 12 is completed, the quartz cap 20 is put onto the opening of the quartz tube 16 to close and seal the quartz tube 16.

Next, the heater 18 is controlled so that the temperature is increased to 1100° C. at a rate of 5° C./minute. Subsequently, annealing treatment (the final high-temperature treatment) is carried out to the semiconductor wafers 12 for 20 minutes. Next, an oxygen gas is introduced into the quartz tube 16, and then, the heater 18 is controlled so that the semiconductor wafers 12 becomes about 900° C. in temperature at a rate of 2.5° C./minute.

As described before, the temperature of the semiconductor wafers 12 may not be lowered intentionally in the oxidizing atmosphere in the furnace 10. In other words, the heater 18 may be maintained being controlled at 1100° C. while the semiconductor wafers 12 are exposed in an oxidizing atmosphere.

After that, the quartz cap 20 is removed from the quartz tube 16 and the semiconductor wafers 12 are taken out of the quartz tube 16, so that the semiconductor wafers 12 are unloaded from the furnace 10.

Since the semiconductor wafers 12 are exposed in an oxidizing atmosphere in the furnace 10 just after the final high-temperature treatment, the amount of fixed electric charge can be controlled to be uniform throughout any locations on the wafer boat 14 (source, center and handle). In other words, ununiformity of fixed charge, caused by newly added fixed charge formed when the wafers 12 are unloaded, can be prevented.

As described above, according to this invention, a semiconductor element (P-type diffused resistor) having a stable density of electric charge (fixed electric charge) on a semiconductor wafer can be provided without lowering a throughput of fabrication.

What is claimed is:

1. A method for fabricating a semiconductor element, comprising:
providing a semiconductor wafer;
forming an oxide layer on the semiconductor wafer;
loading the semiconductor wafer in a furnace;
carrying out a high-temperature thermal treatment to the semiconductor wafer at least once, wherein the high-temperature thermal treatment comprises a final high-temperature treatment, which is carried out lastly as the high-temperature thermal treatment;
maintaining the semiconductor wafer left in the furnace in an oxidizing atmosphere for a predetermined period of time after the final high-temperature treatment; and
unloading the semiconductor wafer from the furnace after the maintaining process in oxidizing atmosphere.

2. A method for fabricating a semiconductor element according to claim 1, wherein
the semiconductor wafer is lowered in temperature to a predetermined lower temperature in the maintaining step.

3. A method for fabricating a semiconductor element according to claim 1, wherein
the high-temperature thermal treatment is carried out plural times.

4. A method for fabricating a semiconductor element according to claim 1, wherein
the final high-temperature treatment is carried out at a temperature that is over 700° C.

5. A method for fabricating a semiconductor element according to claim 3, wherein
the final high-temperature treatment is carried out at a temperature that is over 1000-900° C.

6. A method for fabricating a semiconductor element according to claim 2, wherein
the predetermined lower temperature is about 900° C.

7. A method for fabricating a semiconductor element according to claim 1, wherein
the final high-temperature treatment is carried out intentionally to reduce an electric charge trapped between the oxide layer and the semiconductor wafer.

8. A method for fabricating a semiconductor element according to claim 1, wherein
the semiconductor element comprises a resistive element.

9. A method for fabricating a resistive element on a semiconductor wafer, comprising:
providing a semiconductor wafer;
forming a screen oxide layer on the semiconductor wafer;
forming a diffusion layer on the semiconductor wafer by a first annealing process;
loading the semiconductor wafer into a furnace;
carrying out a final high-temperature treatment, which is carried out lastly as a high-temperature thermal treatment in the furnace;
maintaining the semiconductor wafer left in the furnace in an oxidizing atmosphere for a predetermined period of time after the final high-temperature treatment; and
unloading the semiconductor wafer from the furnace after the maintaining process in oxidizing atmosphere.

10. A method for fabricating a semiconductor element according to claim 9, wherein
the semiconductor wafer is lowered in temperature to a predetermined lower temperature in the maintaining step.

11. A method for fabricating a semiconductor element according to claim 9, wherein
the high-temperature thermal treatment is carried out plural times.

12. A method for fabricating a semiconductor element according to claim 9, wherein
the final high-temperature treatment is carried out at a temperature that is over 700° C.

13. A method for fabricating a semiconductor element according to claim 12, wherein
the final high-temperature treatment is carried out at a temperature that is over 1000-900° C.

14. A method for fabricating a semiconductor element according to claim 10, wherein
the predetermined lower temperature is about 900° C.

15. A method for fabricating a semiconductor element according to claim 9, wherein
the final high-temperature treatment is carried out intentionally to reduce an electric charge trapped between the oxide layer and the semiconductor wafer.
